(19) United States
(12) Patent Application Publication
(10) Pub. No.: US 2025/0098347 A1
(43) Pub. Date: Mar. 20, 2025

(54) SEMICONDUCTOR DEVICE AND METHOD FOR MANUFACTURING A SEMICONDUCTOR DEVICE

(71) Applicant: ams-OSRAM International GmbH, Regensburg (DE)

(72) Inventors: Michael Zitzlsperger, Regensburg (DE); Thomas Schwarz, Regensburg (DE); Tobias Gebuhr, Bad Abbach (DE)

(21) Appl. No.: 18/562,249

(22) PCT Filed: May 25, 2022
(86) PCT No.: PCT/EP2022/064244

§ 371 Date: Nov. 17, 2023

(30) Foreign Application Priority Data
May 27, 2021 (DE) 10 2021 113 715.2

(51) Int. Cl. H01L 27/146; H01L 21/56; H01L 23/00; H01L 23/06; H01L 23/29; H01L 23/31

(52) U.S. Cl. CPC H10F 39/804; H01L 21/56; H01L 23/06; H01L 23/296; H01L 23/3185; H10F 39/809; H01L 24/48; H01L 2224/48225

(57) ABSTRACT

In an embodiment a semiconductor device includes a planar carrier having a main surface on which a semiconductor chip element is mounted, the semiconductor chip element having at least one semiconductor chip, at least one wire connection between the main surface of the carrier and a top surface of the at least one semiconductor chip, a first material completely enclosing the wire connection and comprising a first plastic material and a second material forming a frame and surrounding a cavity, wherein the top surface of the at least one semiconductor chip has a region that is free of the first and second materials and is arranged in the cavity, and wherein the top surface of the at least one semiconductor chip has a region that is free of any material.

### CROSS-REFERENCE TO RELATED APPLICATIONS

This patent application is a national phase filing under section 371 of PCT/EP2022/064244, filed May 25, 2022, which claims the priority of German patent application 102021113715.2, filed May 27, 2021, each of which is incorporated herein by reference in its entirety.

### TECHNICAL FIELD

A semiconductor device and a method for manufacturing a semiconductor device are specified.

### BACKGROUND

There are packaged electronic components, so-called packages, with semiconductor chips where the chip is exposed on its top side and thus not completely enclosed by the package. Such components can also be referred to as “exposed die packages”. It has been shown that with such devices, a completely hard package is associated with the risk of chip lift-off and torn bonding wires, since the design, in which the chip is not completely enclosed by the package, can cause stresses in the package, for example due to the different thermal expansions of chip, package and encapsulation, in extreme cases to cause the chip to lift off the package and, since the environment of the chip is rigidly bonded to it, also cause bonding wires to tear off the substrate in the process.

A soft package material can help avoid this problem. However, this also means that the package as a whole offers little mechanical resistance to deformation and can therefore be damaged during testing or when handling the component.

Furthermore, housing forms are known in which the chip is mounted in a cavity on a first plane, while bonding wires are connected on a second plane of the housing, different from the first plane. With such a stepped cavity, it may be possible that any partial lifting of the chip, if necessary, does not directly affect the bonding wires. A disadvantage of this design, however, is the extremely high cost of the package, for which a multilayer printed-circuit board with stepped cavity is usually used, which costs several times as much as a planar printed-circuit board.

In case a package with a cavity is used in which the mounting surface of the chip and the connection points of the bonding wires are on the same level and are typically close to each other, the cavity is usually filled with a soft material. However, this makes the package as a whole mechanically sensitive and pliable and has a large area around the chip that should not be touched, for example for handling. If, on the other hand, a hard filler material is used, the different thermal expansions of chip, filler material and substrate lead to strong stresses in the package. If, for example, the usual transfer molding process is used for production, this effect is intensified. Here, the high forces during sealing on the top side of the chip may compress the adhesive for chip assembly and push the substrate away from the chip after opening the mold. During soldering or thermal cycling, this can cause the chip to lift off the substrate, which can also tear off the adjacent bond wires.

### SUMMARY

Embodiments provide a semiconductor device. Further embodiments provide a method for manufacturing a semiconductor device.

According to at least one embodiment, a semiconductor device comprises a substrate having a main surface on which a semiconductor chip element is mounted.

According to at least one further embodiment, in a method for manufacturing a semiconductor device, a carrier is provided having a main surface on which a semiconductor chip element is mounted.

The embodiments and features described below apply equally to the semiconductor device and to the method for manufacturing the semiconductor device.

Particularly preferably, the carrier is a planar carrier. For mounting the semiconductor chip element on the carrier, a planar carrier is thus particularly preferred. In particular, this can mean that the carrier has no cavity, i.e. no depression, in which the semiconductor chip element can be mounted. The main surface of the carrier on which the semiconductor chip element is mounted is particularly preferably planar or substantially planar. In this context, planar can in particular mean that height variations of the main surface are smaller than a height of the semiconductor chip element or preferably smaller than 10% of the height of the semiconductor chip element or particularly preferably smaller than 5% of the height of the semiconductor chip element. The carrier can thus be plate-shaped, wherein the underside of the carrier opposite the main surface can be intended and configured for mounting and for electrical contacting of the semiconductor component.

For example, the carrier may be a single-layer carrier or a multilayer carrier, i.e., a carrier comprising a layer of one carrier material or a plurality of layers of one or more carrier materials. The carrier material may be, for example, a plastic or a ceramic material. Thus, the carrier may be, for example, a ceramic carrier or a plastic carrier such as a single-layer or multilayer printed circuit board, for example, a single-layer or multilayer PCB (“printed-circuit board”). For contacting the semiconductor component as well as for electrical connection of the semiconductor chip element, electrical connection points, conductor tracks and electrical vias may be provided.

According to a further embodiment, the semiconductor chip element comprises at least one semiconductor chip. The at least one semiconductor chip has a top surface facing away from the carrier after mounting the semiconductor chip element on the main surface of the carrier. The at least one semiconductor chip may be an electronic semiconductor chip, for example an integrated circuit (IC) or an optoelectronic semiconductor chip, such as a light-emitting diode chip or laser diode chip. Particularly preferably, the semiconductor chip element may have as at least one semiconductor chip an electronic semiconductor chip having the top surface on which an optoelectronic semiconductor chip is mounted. For example, the electronic semiconductor chip may be an integrated circuit, for example based on a silicon chip, which is intended and configured for driving the optoelectronic semiconductor chip. For example, the optoelectronic semiconductor chip may be a pixelated light-emitting diode chip, i.e., a light-emitting diode chip that has a plurality of emitter regions that can be driven independently of one another and are arranged in a matrix-like manner. For mounting the semiconductor chip element, this can be attached to the main surface of the carrier, for example by soldering or gluing, and if necessary, depending on the design of the at least one semiconductor chip, can also be electrically connected from the underside of the semiconductor chip element.

According to a further embodiment, at least one wire connection is provided between the main surface of the carrier and a top surface of the at least one semiconductor chip. In other words, there is electrical contacting between the semiconductor chip element and the carrier via the at least one wire connection, which may in particular have or be one or more bonding wires. On the main surface of the carrier, there may be an electrical connection point for this purpose, to which the bonding wire or wires of the wire connection is or are bonded. On the top surface of the at least one semiconductor chip, a corresponding electrical connection point may also be present. The semiconductor chip element with the at least one semiconductor chip is thus mounted on the carrier and electrically contacted at least with the at least one wire connection between the main surface of the carrier and the top surface of the semiconductor chip.

According to a further embodiment, the semiconductor device further comprises a first material and a second material. The first material and the second material are different from each other and are applied, in particular successively, to the carrier, i.e. to the main surface of the carrier. The first and second materials are in particular intended and configured to form, together with the carrier, a housing body in which the semiconductor chip element remains at least partially exposed. Particularly preferably, the first and second materials are applied to the carrier after the semiconductor chip element has been mounted.

According to a further embodiment, the first material completely encloses the at least one wire connection. In particular, this means that the at least one wire connection is enclosed with the first material after the main surface of the carrier is electrically connected to the top surface of the at least one semiconductor chip of the semiconductor chip element, so that the wire connection, i.e. preferably the one or more bonding wires including the electrical connection points at the main surface of the carrier and at the top surface of the at least one semiconductor chip, are covered with the first material. If there is a plurality of wire connections, they are all completely enclosed by the first material, and the first material may be applied to the carrier contiguously or in regions separated from each other.

According to another embodiment, the second material forms a frame. In particular, the frame may be formed on the main surface of the support. The second material may surround a cavity such that a depression is formed by the second material.

According to a further embodiment, the top surface of the at least one semiconductor chip has a region which is free of the first and second material and which is arranged in the cavity. Particularly preferably, only the portion of the top surface of the semiconductor chip that is located in the region of the at least one wire connection is covered with the first material so as to completely enclose the at least one wire connection with the first material. This portion may particularly preferably be located in an edge region of the top surface of the at least one semiconductor chip, so that only the edge region or even only one or more parts of the edge region are covered with first material. Furthermore, particularly preferably no part of the top surface or only the part covered by the first material is covered with the second material. Thus, preferably, the entire region of the top surface of the at least one semiconductor chip that is free of the first material is also free of the second material. Further, the top surface of the semiconductor chip may have a region that is free of any material. In other words, this may particularly mean that the semiconductor chip is not covered by any solid material of the completed semiconductor device in the region that is free of any material. Thus, the region that is free of any material may be in direct contact with the atmosphere of the environment in which the semiconductor device is situated, which may be air, for example.

In the case that the semiconductor chip element comprises as at least one semiconductor chip an electronic semiconductor chip having the top surface on which an optoelectronic semiconductor chip is mounted, the optoelectronic semiconductor chip is particularly preferably arranged spaced apart from the first and second materials in the cavity. In other words, in this case, the optoelectronic semiconductor chip is particularly preferably arranged on the region of the top surface of the electronic semiconductor chip that is free of the first and second materials.

According to a further embodiment, the first material comprises or consists of a first plastic material. The first material, i.e. in particular the first plastic material, is particularly preferably applied by a process which exerts possibly no forces or as few forces as possible on the at least one wire connection. Particularly preferably, the first material is applied by means of vacuum injection molding (VIM). In this case, at least the first plastic material is molded onto the at least one wire connection using a vacuum, completely enclosing the at least one wire connection. When vacuum injection molding is used, the sealing forces are significantly smaller than with the usually used transfer molding. Furthermore, the forces acting on the semiconductor chip element are lower than in the case of injection molding, and the stress on the carrier and the compression of any adhesive used for mounting the semiconductor chip element are lower. Alternatively or additionally, a film-assisted molding (FAM) process, a casting process, a spraying process, a sacrificial layer process or a combination of the aforementioned processes can be used to apply the first material, i.e. at least the first plastic material, and thus to enclose the at least one wire connection.

Particularly preferably, the first material is at least partially soft and/or elastic. Accordingly, at least the first plastic material is soft and/or elastic. In other words, the first material, i.e. at least the first plastic material, is not rigid but plastically and/or elastically deformable even under the action of small forces, so that in the case of stresses which may occur, for example, due to different coefficients of thermal expansion during temperature changes, for example during soldering of the semiconductor device, the mechanical load on the at least one wire connection can be minimized. Particularly preferably, a material described as soft and/or elastic may have a modulus of elasticity of less than 1 GPa or less than 500 MPa or even less than 100 MPa.

Particularly preferably, the first plastic material may comprise or be silicone. Particularly preferably, the silicone may have a modulus of elasticity greater than or equal to 1 MPa and less than or equal to 50 MPa. For example, the silicone may also be a black silicone that can serve as a radiation shield. Furthermore, the first plastic material may also comprise or be made of, for example, an epoxy, particularly preferably with a plasticizer.

Further, the first material may include a second plastic material that is different from the first plastic material and the second material. For example, the second plastic material may be arranged on the first plastic material and, together with the first plastic material, may completely enclose the at least one wire connection. Preferably, the second plastic material may be soft and/or resilient. In particular, the second plastic material may comprise or be made of a silicone. Further, the second plastic material may, for example, comprise or be an epoxy. For example, the epoxy may have a modulus of elasticity greater than or equal to 1 GPa and less than or equal to 10 GPa. Materials comprising an epoxy particularly include silicone-epoxy hybrid materials. For example, two different silicones or a silicone and an epoxy or a silicone and a silicone-epoxy hybrid material may be used for the first and second plastic materials. In particular, the second plastic material can be applied using a process described in advance for the first plastic material.

According to another embodiment, the second material comprises one or more materials selected from a third plastic material, a semiconductor material, and a metal material. Particularly preferably, the second material is rigid. In the case of a semiconductor material, for example, silicon may be used for the second material. In the case of a metal material, steel may be used, for example. By having a rigid second material, a rigid and thus non-elastic frame can be formed on the carrier, which can be advantageous for the stability of the semiconductor device. By encasing the at least one wire connection with the first material, which is preferably at least partially soft and/or elastic, the at least one wire connection may be protected from stresses, as described further above, even if such stresses occur, for example, between the carrier and the second material.

Preferably, the third plastic material may have or be a thermoset. Particularly preferably, the third plastic material may comprise or be an epoxy, especially a rigid epoxy. Highly filled epoxy materials may be particularly preferred, by means of which the mechanical properties, such as hardness, coefficient of thermal expansion, modulus of elasticity, etc., can be optimized and adapted to the joining partners. Furthermore, the second material can also comprise or be made of a silicone, for example a black silicone. If only plastic materials are used for the first and second materials, it can be particularly advantageous if the first and second materials are applied using the same molding tool. For example, the carrier with the assembled and electrically contacted semiconductor chip element can be placed in a molding tool in which first the first material is molded onto the at least one wire connection and then the second material is molded onto the carrier. The third plastic material can be applied, for example, by means of transfer molding or another process mentioned in connection with the first plastic material.

According to a particularly preferred embodiment, the at least one wire connection, i.e. at least one bonding wire including the connection points, is embedded in the soft first material, for example silicone, by means of vacuum injection molding, and this is then in turn embedded in the harder second material, for example epoxy.

For example, the first material may be at least partially arranged on and/or under the second material as viewed from the substrate. Further, the first material may be at least partially arranged within the cavity formed by the second material. For example, the first material may partially or completely cover the second material. Further, it may also be possible for the first material to completely cover the second material except for a viewing window. Through the viewing window, which may be filled with a, preferably transparent, filler material such as a transparent silicone, a part of a surface of the second material may be visible, for example with a marking. Alternatively, the second material may partially or completely cover the first material.

In particular, the first and second materials may be formed such that the semiconductor device has a top surface facing away from the substrate that is planar and has an opening, at least partially formed by the cavity, through which a portion of the semiconductor chip is exposed.

Furthermore, a cover element comprising a wavelength conversion material and/or a window element and/or a protective foil may be arranged in or on the cavity above the semiconductor chip element. Particularly preferably, the cover element may be spaced from the semiconductor chip element.

In the semiconductor device described here, the problems of hard or soft packages described above can be significantly reduced. In particular, it may be advantageous to fabricate only the region immediately adjacent to the at least one wire connection from the soft first material. By embedding the at least one wire connection in the soft first material, it can be achieved that the wire connection can be largely decoupled from mechanical stresses and strains of the rest of the semiconductor device.

Further, it is not necessary to have a stepped cavity carrier, i.e., stepped main surface, in which the at least one semiconductor chip is mounted on a first plane and the connection point or points for the at least one wire connection are arranged on a second plane different from the first plane.

The use of the first and second materials, especially preferably using the described application methods for the first material, can result in increased mechanical stability and cycle strength with a planar package design.

Further advantages, advantageous embodiments and further developments are revealed by the embodiments described below in connection with the figures.

### BRIEF DESCRIPTION OF THE DRAWINGS

FIGS. 1A and 1B show schematic illustrations of a semiconductor device according to an embodiment;

FIGS. 2A to 3B show schematic illustrations of a semiconductor device according to further embodiments;

FIGS. 4A and 4B show schematic illustrations of a semiconductor device according to a further embodiment;

FIGS. 5A to 5D show schematic illustrations of process steps of a method for manufacturing a semiconductor device according to an embodiment;

FIGS. 6A and 6B show schematic illustrations of a semiconductor device according to a further embodiment;

FIGS. 7A to 7D show schematic illustrations of process steps of a method for manufacturing a semiconductor device according to an embodiment;

FIGS. 8A and 8B show schematic illustrations of a semiconductor device according to a further embodiment;

FIGS. 9A to 9D show schematic illustrations of process steps of a method for manufacturing a semiconductor device according to an embodiment; and

FIGS. 10A to 10D show schematic illustrations of a semiconductor device according to further embodiments.

In the embodiments and figures, identical, similar or identically acting elements are provided in each case with the same reference numerals. The elements illustrated and their size ratios to one another should not be regarded as being to scale, but rather individual elements, such as for example layers, components, devices and regions, may have been made exaggeratedly large to illustrate them better and/or to aid comprehension.

### DETAILED DESCRIPTION OF ILLUSTRATIVE EMBODIMENTS

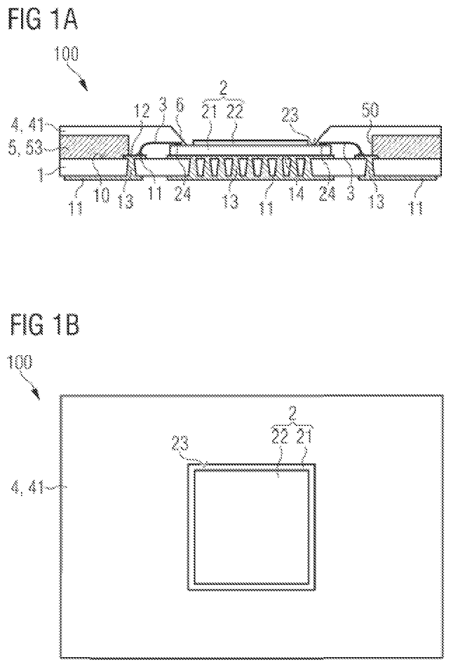

FIGS. 1A and 1B show a sectional view (FIG. 1A) and a top view (FIG. 1B) of a semiconductor device 100 according to an embodiment.

The semiconductor device 100 has a carrier 1 with a main surface 10 on which a semiconductor chip element 2 is mounted, which has at least one semiconductor chip 21, for example an electronic semiconductor chip such as an integrated circuit or an optoelectronic semiconductor chip such as a light-emitting diode chip or laser diode chip. In the embodiment shown, the semiconductor chip element 2 has, purely by way of example, as at least one semiconductor chip 21 an electronic semiconductor chip on which a further semiconductor chip 22 formed by an optoelectronic semiconductor chip is mounted and electrically connected. The electronic semiconductor chip 21 is, for example, an integrated circuit, for example based on a silicon chip, which is intended and configured for driving the optoelectronic semiconductor chip. The at least one semiconductor chip 21 has a top surface 23 which faces away from the carrier 1 and on which the optoelectronic semiconductor chip 22 is mounted in the embodiment shown, for example by soldering. For example, the optoelectronic semiconductor chip 22 may be a pixelated light-emitting diode chip, i.e., a light-emitting diode chip having a plurality of independently controllable emitter regions arranged in a matrix-like manner. For example, the optoelectronic semiconductor chip 22 may have a matrix of 10×10 emitter regions. Such a semiconductor chip may be advantageous, for example, for adaptive lighting, such as in the automotive field.

As shown, the carrier 1 is preferably a planar carrier that does not have a cavity, i.e., a recess, in which the semiconductor chip element 2 can be mounted. The main surface 10 of the carrier 1, on which the semiconductor chip element 2 is mounted, is particularly preferably planar or substantially planar. The carrier 1 can thus be plate-shaped, wherein the underside of the carrier 1 opposite the main surface 10 is intended and configured for mounting and for electrical contacting of the semiconductor component 100.

For example, the carrier 1 may be a single-layer carrier or a multilayer carrier, that is, a carrier comprising a layer of one carrier material or a plurality of layers of one or more carrier materials. The carrier material may be, for example, a plastic or a ceramic material. Thus, the carrier may be, for example, a ceramic carrier or a plastic carrier such as a single-layer or multilayer printed circuit board, for example, a single-layer or multilayer PCB (“printed circuit board”). In the present as in the further embodiments, a single-layer PCB is shown as a carrier 1 purely by way of example. Electrical connection points 11, conductor tracks 12 and electrical vias 13 are provided for contacting the semiconductor component 100 and for electrical connection of the semiconductor chip element 2.

For mounting the semiconductor chip element 2 on the carrier 1, the latter can be fastened to the main surface 10 of the carrier 1, for example, by means of soldering or bonding and, if necessary, can also be electrically connected from the underside of the semiconductor chip element 2. In the embodiment shown, the semiconductor chip element 2 with the at least one semiconductor chip 2 is attached to a mounting pad 14, which is connected to a connection point 11 for dissipating heat from the semiconductor chip element 2 via a plurality of vias 13.

At least one wire connection 3 is provided between the main surface 10 of the carrier 1 and the top surface 23 of the at least one semiconductor chip 21. In the illustrated embodiment, as shown, a plurality of wire connections 3 are provided. In other words, electrical contacting exists between the semiconductor chip element 2 and the carrier 1 via the at least one wire connection 3, which may in particular comprise or be one or more bonding wires. On the top surface 23, the at least one semiconductor chip 21 of the semiconductor chip element 2 has electrical connection points 24 for this purpose. Furthermore, electrical connection points 11 are provided on the main surface 10 of the carrier 1. The respective bonding wire or wires of the wire connections 3 are bonded to the connection points 11, 24. The semiconductor chip element 2 with the at least one semiconductor chip 21 is thus mounted on the carrier 1 and electrically contacted with at least one or, as shown, a plurality of wire connections 3 between the main surface 10 of the carrier 1 and the top surface 23 of the at least one semiconductor chip 2.

The semiconductor device 100 further comprises a first material 4 and a second material 5, which are deposited on the main surface 10 of the carrier 1. The first material 4 and the second material 5 are different from each other and are deposited, in particular successively, on the carrier 1, i.e. on the main surface 10 of the carrier 1. The first and second materials 4, 5 are in particular intended and configured to form, together with the carrier 1, a housing body in which the semiconductor chip element 2 remains at least partially exposed. Particularly preferably, the first and second materials 4, 5 are applied to the carrier 1 after the semiconductor chip element 2 has been mounted. Furthermore, in the shown embodiment, it may also be possible that the second material 5 is applied to the carrier 1 before the semiconductor chip element 2.

The first material 4 completely encloses the wire connections 3. In particular, this means that after the main surface 10 of the carrier 1 is electrically connected to the top surface 23 of the at least one semiconductor chip 21 of the semiconductor chip element 2, the wire connections 3 are enclosed with the first material 4 so that the wire connections 3, i.e. the bonding wires including the electrical connection points 11, 24 on the main surface 10 of the carrier 1 and on the top surface 24 of the at least one semiconductor chip 21, are covered with the first material 4.

The second material 5 forms a frame on the main surface 10 of the carrier 1. The second material 5 surrounds a cavity 50 so that a depression is formed by the second material 5. The semiconductor chip element 2 is arranged in the cavity 50 and spaced apart from the second material 5 in the shown embodiment. In the space between the semiconductor chip element 2 and the second material 5, the wire connections 3 are arranged surrounded by the first material 4.

The top surface 23 of the at least one semiconductor chip 21 of the semiconductor chip element 2 has a region which is free of the first and second materials 4, 5 and which is arranged in the cavity 50. In particular, only the portion of the top surface 23 of the semiconductor chip 21 that is located in the region of the wire connections 3 is covered with the first material 4, so as to completely surround the wire connections 3 with the first material 4. As can be seen in FIGS. 1A and 1B, this portion is located in an edge region of the top surface 23 of the at least one semiconductor chip 21, so that only the edge region of the top surface 23 in which the connection points 24 are arranged is covered with the first material 4. As a result, the semiconductor device 100 has an opening 6 on its top surface. The further semiconductor chip 22, i.e. the optoelectronic semiconductor chip, is completely free of the first and second materials 4, 5 and is thus exposed and accessible from the top side of the semiconductor device 100 in the opening 6. In other words, the semiconductor chip 21 has a region that is free of any material of the semiconductor device 100 and thus also exposed and accessible. Further, therefore, the further semiconductor chip 22 also has a region that is free of any material of the semiconductor device 100.

The first material 4 comprises a first plastic material 41. In particular, the first material 4 may consist of the first plastic material 41. The first plastic material 41 has silicone or is particularly preferably a silicone. This may also be a black silicone, which may serve as a radiation shield. In particular, the first plastic material 41 and thus the first material 4 is soft and/or elastic and thus plastically and/or elastically deformable, so that the wire connections 3 enclosed by the first material 4 can be protected from mechanical stresses and strains in the semiconductor device 100.

The first material 4, i.e. the first plastic material 41, is particularly preferably applied using a process that exerts possibly no forces, or at least as few forces as possible, on the wire connections 3. Particularly preferably, the first material 4 is applied by means of vacuum injection molding. In this case, the first plastic material 41 is molded onto the wire connections using a vacuum to completely enclose the wire connections 3. By vacuum injection molding, for example, a good seal can be achieved on the semiconductor chip 21 using a low sealing force. Furthermore, there is little risk of deformation of the wire connections 3 and little risk of chip lift-off when the wire connections 3 are enclosed. Alternatively or additionally, a film-assisted molding process, a casting process, a spraying process, a sacrificial layer process or a combination of said processes may be used for applying the first material 4, i.e. at least the first plastic material 41, and thus for wrapping the wire connections 3. Furthermore, as will be described further below, the first material 4 may also comprise, for example, at least one further plastic material, referred to herein and hereinafter as the second plastic material, which together with the first plastic material 41 forms the first material.

As can be seen in FIGS. 1A and 1B, the first material 4 completely covers the second material 5 and thus can also serve as protection, for example as radiation protection in the case of a black silicone, for the second material 5. The second material 5 has a rigid material and serves as a hard stiffening frame. For example, the second material 5 may have or be a third plastic material 53, which may preferably have or be an epoxy, in particular a highly filled epoxy. Further, a silicone-epoxy hybrid material may also be used. Alternatively, for example, a liquid-crystal polymer (LCP) material or a semiconductor material such as silicon or a metal material such as steel or a combination thereof are also possible. In the case of a plastic material, the second material 5 may preferably be molded to the frame, for example by means of an transfer molding process. In the case of a semiconductor material or a metal material, the second material 5 may, for example, form a prefabricated frame which is glued to the main surface 10 of the carrier.

In the semiconductor device 100 according to FIGS. 1A and 1B, the semiconductor chip element 2, i.e. in particular the semiconductor chips 21, 22, is seated in the cavity 50 formed by the rigid second material 5, while the wire connections 3 and the edge region of the top surface 23 of the semiconductor chip 21 are formed by the first material 4 and are thus protected. The top surface of the semiconductor device 100 formed by the first material 4 is planar and without, for example, an undefined under-potting. As a result, the semiconductor device 100 provides defined surfaces and, in particular, a smooth and large surface for handling by means of vacuum pick-ups, for example. Due to the second material 5 and the resulting stiffening, the semiconductor component 5 nevertheless exhibits good shape constancy.

In the following figures, further embodiments and modifications of the semiconductor device 100 according to further embodiments are shown. The following description essentially refers to the differences from the respective preceding embodiments. Features not described may be embodied as described in advance in each case.

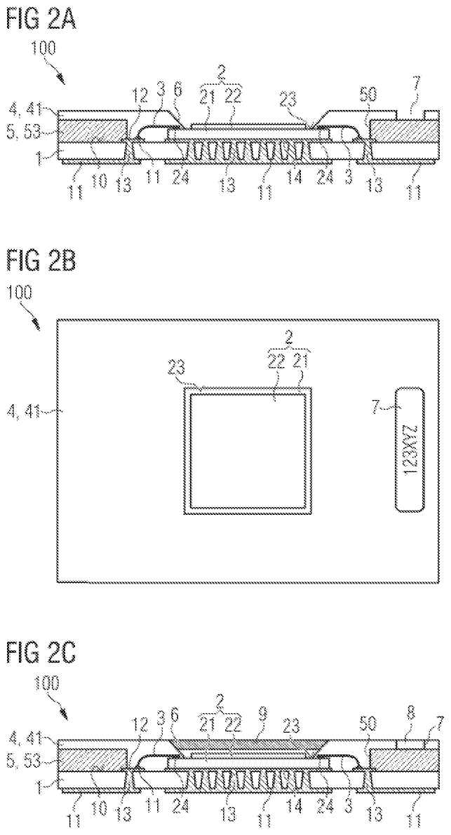

In FIGS. 2A and 2B, a semiconductor device 100 according to a further embodiment is shown in a sectional view and a top view, which additionally has a viewing window 7 in the first material 4. In other words, in this embodiment, the first material 4 completely covers the second material 5 except for the viewing window 7. Through the viewing window 7, a part of a surface of the second material 5 may be visible. As indicated in FIG. 2B, the second material 5, i.e., the stiffening frame of the semiconductor device 100, may have a marking, such as a laser marking, or other identification applied thereto.

FIG. 2C shows a sectional view of a further embodiment in which the viewing window 7 is filled with a filler material 8. The filler material 8 can, for example, be white or whitish or, particularly preferably, transparent and, for example, have or be a silicone.

Further, as indicated in FIG. 2C, a cover element 9 may be arranged in or on the cavity 50, and thus in or on the opening 6 above the semiconductor chip element 2. For example, the cover element 9 may comprise or be a wavelength conversion material and/or a window element and/or a protective film. Particularly preferably, the cover element 9 may be spaced from the semiconductor chip element 2 as indicated in FIG. 2C.

Even though the semiconductor devices according to the following embodiments are shown without a viewing window and without a cover element, a viewing window and/or one or more cover elements may be provided as previously described.

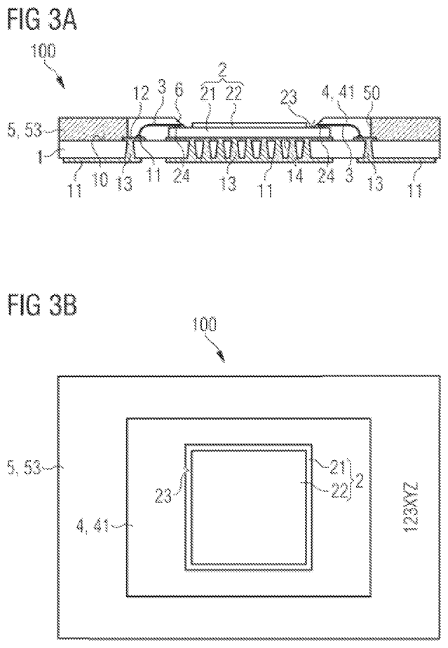

FIGS. 3A and 3B show, in a sectional view and a top view, another embodiment of the semiconductor device 100 in which the first material 4 is arranged only in the cavity 50 of the second material 5. The top surface of the second material 5 facing away from the substrate 1 is thus free of the first material 4 and thus forms part of the top surface of the semiconductor device 100. The stiffening frame formed by the second material 5 thus remains largely free at the top in this embodiment. A channel (not shown) for the molding compound may here lie on top of or also below the second material 5. Purely by way of example, a marking is shown on the top surface of the second material 5.

In the following figures, for the sake of clarity, not all elements of the semiconductor device 100 are provided with reference numerals.

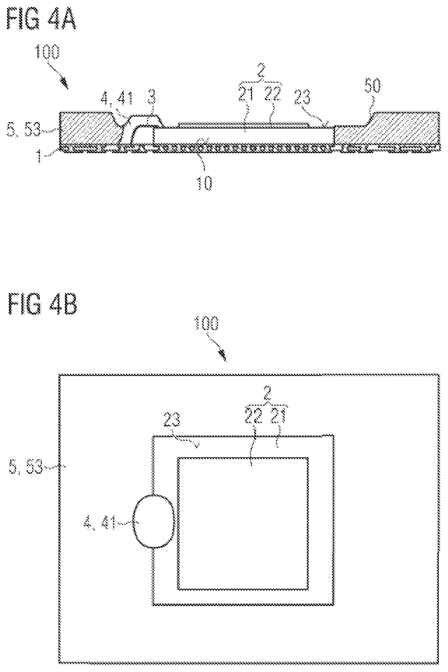

FIGS. 4A and 4B show, in a sectional view and a top view, a further embodiment of the semiconductor device 100 in which the first material 4 is arranged only in the region of the single wire connection 3 in this embodiment. The second material 5, which may particularly preferably in this embodiment comprise a third plastic material 53 formed by a black epoxy, may be adjacent to the semiconductor chip element 2 except in the region of the wire connection 3 and may for example be formed onto the main surface 10 of the carrier by a molding process. Thus, the entire housing part on the carrier 1 may be producible by molding processes.

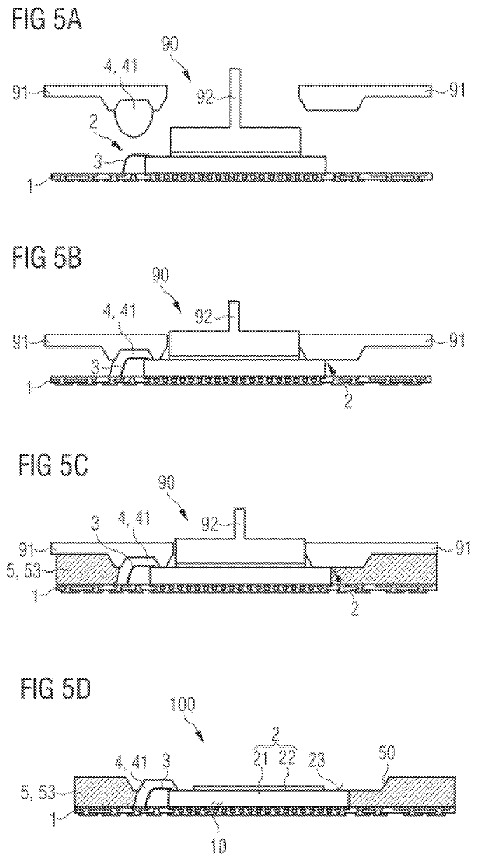

FIGS. 5A to 5D show process steps of a method for manufacturing the semiconductor device 100 of FIGS. 4A and 4B. In a first method step, the semiconductor chip element 2 is mounted on the support 1 and electrically contacted via the wire connection 3. As shown in FIGS. 5A and 5B, by means of a molding tool 90 having a molding tool part 91, the first material 4 formed by the first plastic material 41 is applied to enclose the wire connection 3. By closing the molding tool part 91, as shown in FIG. 5B, a kind of dome of the soft and/or elastic first material 4 can be formed over the wire connection 3, which completely encloses the wire connection 3, but is only arranged in the region of the wire connection 3. By means of an optional further molding tool part 92, which can be separately movable, the top surface of the semiconductor chip element 2, in particular the optoelectronic semiconductor chip, can be protected.

Using the same molding tool 90, as shown in FIG. 5C, the second material 5 can be formed on the carrier 1 around the semiconductor chip element 2 with the first material 4 in a further process step. Optionally, a portion of the top surface of the electronic semiconductor chip of the semiconductor chip element 2 may also be overmolded with the second material 5. In the method shown, it is particularly advantageous that only the immediate surroundings of the wire connection 3 are formed by a soft material. This environment can be made very small, an undercut of the hard body formed by the second material 5 is possible.

By curing the second material 5 and removing the molding tool 90, the semiconductor device 100 can be completed, as shown in FIG. 5D.

Although FIGS. 5A to 5D and further figures show methods of fabricating a single semiconductor device 100, it may also be possible to fabricate a plurality of semiconductor devices in a composite that can be separated into separate semiconductor devices after curing.

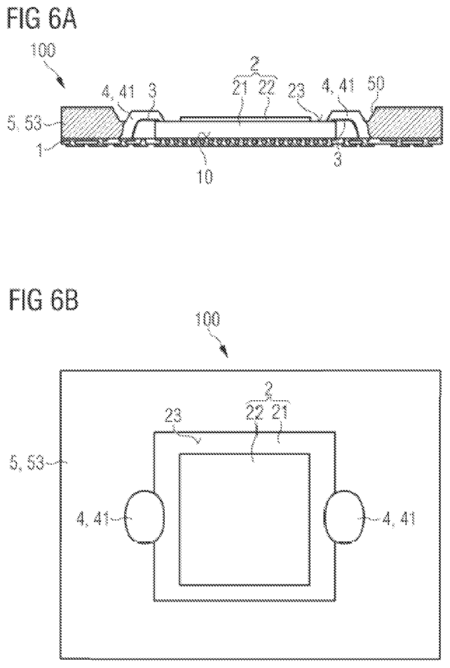

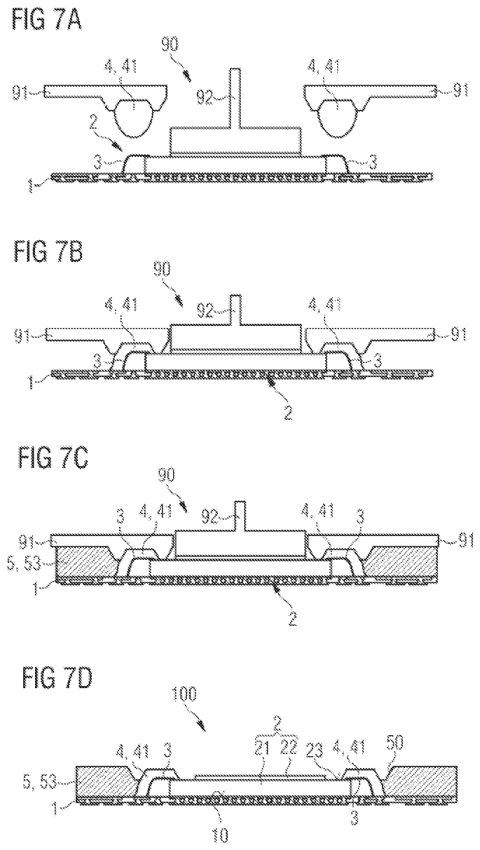

The method described is independent of the number of wire connections 3. For example, FIGS. 6A and 6B and FIGS. 7A to 7D show a semiconductor device 100 and a method for manufacturing the same in which there are two opposing wire connections 3 enclosed by respective separate parts formed of the first material 4.

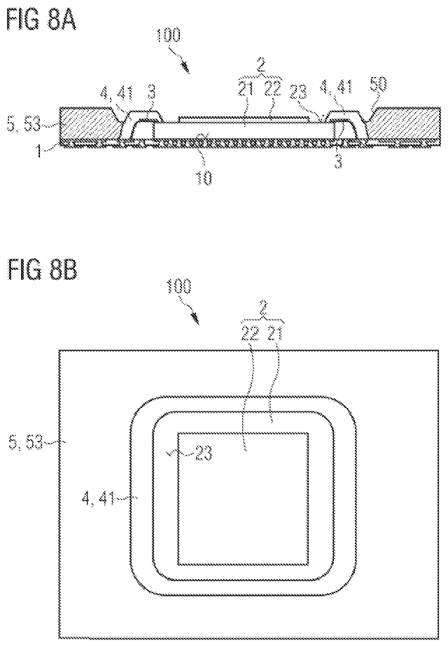

FIGS. 8A and 8B show an embodiment in which wire connections 3 are present all around the semiconductor chip element 2, i.e. on all four sides. In this case, the first material 4 can be formed in the shape of a frame by means of the method described above, for example, as shown, or can also be applied in separate parts to the wire connections 3. By simply adapting the molding tool 90, any number of wire connections 3 can thus be enclosed using the process described.

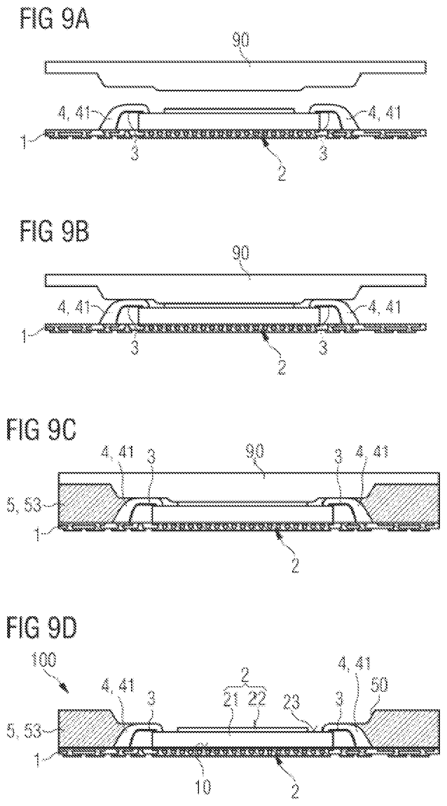

FIGS. 9A to 9D show method steps for a method for manufacturing a semiconductor device 100 according to a further embodiment, in which the molding tool for forming the second material 5 is shaped such that the second material 5 is formed thicker and can thus form a more stable frame. The second material 5 thus forms a molded body with a deeper cavity in which the semiconductor chip element is arranged. For example, a cover element can be arranged in the cavity at a distance from the semiconductor chip element 3 or directly on top of it. For example, a wavelength conversion material can be molded into the cavity, a glass window can be inserted, or, due to the depth of the cavity, a protective film can be spaced thereover.

Alternatively or in addition to the embodiments and process steps shown, several vacuum injection molding steps or combinations of vacuum injection molding with other molding processes, such as injection molding, can also be carried out and combined in succession, for example.

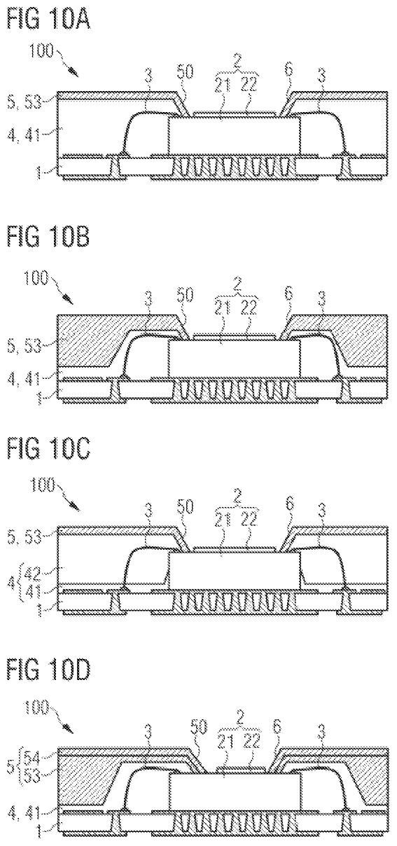

FIG. 10A shows an embodiment of the semiconductor device 100 in which a radiation insensitive protective layer formed of the second material 5 is deposited over the first material 4. For both materials 4, 5, vacuum injection molding may be used for fabrication. For example, the first material 4 can form a mechanically stable molded body, for example made of a first plastic material 41 comprising a, preferably soft, epoxy, while the second material 5 comprises a third plastic material 53 formed of a black silicone. Since both materials are produced in an injection molding process, the surfaces and layer thicknesses are well defined. Advantageously, the embodiment shown exhibits high rigidity over a large component region, in particular over the wire connections 3. Furthermore, there is the advantage of a protection for the epoxy to avoid UV light or blue light induced aging.

FIG. 10B shows an embodiment in which the first material comprises a first plastic material 41 formed by a silicone, while the second material 5 comprises a third plastic material 53 formed by a, preferably rigid, epoxy. Thus, a mechanically stable body in the form of the second material 5 is applied over a flexible molded body formed by the first material 4.

Both the first and second materials may comprise more than one plastic material, as shown in the following embodiments. This allows, for example, sequences of soft, hard and again soft layers to be created.

FIG. 10C shows a further embodiment in which the first material 4 comprises, in addition to the first plastic material 41, a second plastic material 42 applied over the first plastic material 41. The plastic materials 41, 42 may be the same or preferably different from each other and may be applied by an identical or different process. For example, the first plastic material 41 may be a silicone applied by means of vacuum injection molding or by means of mask-assisted spraying, while the second plastic material 42 may be an epoxy applied by means of vacuum injection molding or may also be a silicone. On top of this, as in the embodiment of FIG. 10A, a second material 5 comprising a third plastic material 53 formed of a black silicone is applied preferably by vacuum injection molding. The semiconductor device 100 shown has, in particular, a high stiffness over a large device region and a high stiffness in the region over the wire connections 3. Furthermore, a stress reduction can be achieved in particular by the soft silicone layer between the carrier 1 and the epoxy layer, a protection of the wire connections 3 by the epoxy layer, a protection against light aging of the epoxy by the black silicone and a large light-emitting region.

FIG. 10D shows a further embodiment in which the first material 4 is formed, as in the embodiment of FIG. 10A, by a first plastic material 41 which comprises or is a silicone applied by vacuum injection molding and which may, for example, be optically clear. The second material 5 has a third plastic material 53 made of an optically clear or black rigid epoxy, and above that a fourth plastic material 54 made of a black silicone. The semiconductor device 100 shown, like the previous embodiment, has in particular a high stiffness over a large device region and a high stiffness in the region over the wire connections 3. Furthermore, stress reduction can be achieved in particular by the soft silicone layer between the substrate 1 and the epoxy layer, and protection against light aging of the epoxy can be achieved by the black silicone.

The features and embodiments described in connection with the figures can be combined with each other according to further embodiments, even if not all combinations are explicitly described. Furthermore, the embodiments described in connection with the figures may alternatively or additionally have further features according to the description in the general part.

1.-19. (canceled)

20. A semiconductor device comprising:
a planar carrier having a main surface on which a semiconductor chip element is mounted, the semiconductor chip element having at least one semiconductor chip;
at least one wire connection between the main surface of the carrier and a top surface of the at least one semiconductor chip;
a first material completely enclosing the wire connection and comprising a first plastic material; and
a second material forming a frame and surrounding a cavity,
wherein the top surface of the at least one semiconductor chip has a region that is free of the first and second materials and is arranged in the cavity, and
wherein the top surface of the at least one semiconductor chip has a region that is free of any material.

21. The semiconductor device according to claim 20, wherein the semiconductor chip element comprises, as the at least one semiconductor chip, an electronic semiconductor chip having the top surface on which an optoelectronic semiconductor chip is mounted, the optoelectronic semiconductor chip being spaced apart from the first and second materials in the cavity.

22. The semiconductor device according to claim 20, wherein the first plastic material is soft and/or elastic.

23. The semiconductor device according to claim 20, wherein the first plastic material comprises silicone.

24. The semiconductor device according to claim 20, wherein the first material comprises a second plastic material different from the first plastic material and from the second material, which is arranged on the first plastic material and which, together with the first plastic material, completely encloses the at least one wire connection.

25. The semiconductor device according to claim 20, wherein the second material is rigid.

26. The semiconductor device according to claim 20, wherein the second material comprises one or more materials selected from a third plastic material, a semiconductor material, or a metal material.

27. The semiconductor device according to claim 26, wherein the third plastic material comprises an epoxy or a black silicone.

28. The semiconductor device according to claim 26, wherein the semiconductor material comprises silicon.

29. The semiconductor device according to claim 26, wherein the metal material comprises steel.

30. The semiconductor device according to claim 20, wherein the first material is at least partially deposited on the second material as viewed from the carrier.

31. The semiconductor device according to claim 30, wherein the first material completely covers the second material.

32. The semiconductor device according to claim 30, wherein the first material completely covers the second material except for a viewing window.

33. The semiconductor device according to claim 20, wherein the first material is arranged in the cavity.

34. The semiconductor device according to claim 20, wherein the second material covers the first material.

35. The semiconductor device according to claim 20, wherein the semiconductor device has a top surface facing away from the carrier, which top surface is planar and has an opening through which a portion of the semiconductor chip is exposed.

36. The semiconductor device according to claim 20, further comprising a cover element comprising a wavelength conversion material and/or a window element and/or a protective film, wherein the cover element is arranged in or on the cavity above the at least one semiconductor chip.

37. A method for manufacturing the semiconductor device according to claim 20, the method comprising:
mounting a semiconductor chip element having at least one semiconductor chip on a carrier and electrically contacting a main surface of the carrier and a top surface of the at least one semiconductor chip with at least one wire connection;
completely enclosing the at least one wire connection with a first material comprising a first plastic material by vacuum injection molding, by a film-assisted molding process, by a casting process, by a spraying process, and/or by a sacrificial layer process; and
applying a second material to the carrier, forming a frame and surrounding a cavity,
wherein the top surface of the semiconductor chip has an region that remains free of the first and second plastic materials and is arranged in the cavity.

38. The method according to claim 37, wherein the first and second materials are applied using the same molding tool.

39. A semiconductor device comprising:
a planar carrier having a main surface on which a semiconductor chip element is mounted, the semiconductor chip comprising at least one semiconductor chip;
at least one wire connection between the main surface of the carrier and a top surface of the at least one semiconductor chip;
a first material completely enclosing the wire connection and comprising a first plastic material; and
a second material forming a frame and surrounding a cavity,
wherein the top surface of the at least one semiconductor chip has a region that is free of the first and second materials and is arranged in the cavity,
wherein the top surface of the semiconductor chip has a region that is free of any material,
wherein the semiconductor chip element comprises, as the at least one semiconductor chip, an electronic semiconductor chip having the top surface on which an optoelectronic semiconductor chip is mounted, the optoelectronic semiconductor chip being spaced apart from the first and second materials in the cavity.
